(19) United States
(12) Patent Application Publication
(10) Pub. No.: US 2026/0101642 A1
(43) Pub. Date: Apr. 9, 2026

(54) DISPLAY PANEL AND PREPARATION METHOD FOR THE SAME, AND EVAPORATION DEVICE

(71) Applicants: Hefei Visionox Technology Co., Ltd., Hefei (CN); Visionox Technology Inc., Kunshan (CN)

(72) Inventors: Zhao ZU, Hefei (CN); Peng QIN, Kunshan (CN)

(73) Assignees: Hefei Visionox Technology Co., Ltd., Hefei (CN); Visionox Technology Inc., Kunshan (CN)

(21) Appl. No.: 19/342,719

(22) Filed: Sep. 29, 2025

(30) Foreign Application Priority Data
Oct. 8, 2024 (CN) 202411398636.6

(51) Int. Cl. H10K 59/122; H10K 59/12; H10K 71/16

(52) U.S. Cl. CPC H10K 59/122; H10K 59/1201; H10K 71/16

(57) ABSTRACT

The present application provides a display panel and a preparation method for the same, and an evaporation device. The display panel includes an isolation structure and a light-emitting unit. The isolation structure includes a support portion, and the light-emitting unit includes a first functional layer. The first functional layer includes a film thickness reduction region. A distance between an end of the support portion away from the substrate and an end of the support portion close to the substrate is a first height, and a width of the film thickness reduction region is a first width. The first width is less than or equal to 1.3 times the first height, which is conducive to reducing lateral leakage current of the light-emitting unit.

### CROSS-REFERENCE TO RELATED APPLICATIONS

The present application claims priority to Chinese Patent Application No. 202411398636.6, filed on Oct. 8, 2024 and entitled “DISPLAY PANEL AND PREPARATION METHOD FOR THE SAME, EVAPORATION DEVICE, DISPLAY APPARATUS”, which is incorporated herein by reference in its entirety.

### FIELD

The present application relates to the field of display technology, and in particular to a display panel and a preparation method for the same, and an evaporation device.

### BACKGROUND

An organic light-emitting diode (OLED) is an organic thin-film electroluminescent unit, which has received great attention and has been widely used in electronic display products thanks to its advantages such as simple preparation process, low cost, low power consumption, high luminance, wide angle of view, high contrast, and enabling flexible display.

However, current electronic display products are limited by their structural design, making it difficult to meet needs of users.

### SUMMARY

In view of this, an objective of the present application is to propose a display panel and a preparation method for the same, an evaporation device, and a display apparatus. The display panel can reduce the risk of lateral leakage current and improve the low grayscale color mixing phenomenon.

Based on the objective, a first aspect of the present application discloses a display panel. The display panel includes:
a substrate;
an isolation structure located on a side of the substrate and including at least a support portion; and
at least one light-emitting unit located on the same side of the substrate as the isolation structure and including a first functional layer, the first functional layer including a film thickness reduction region, where
in a direction perpendicular to a plane in which the substrate is located, a distance between an end of the support portion away from the substrate and an end of the support portion close to the substrate is a first height; and in a direction parallel to the plane in which the substrate is located and from the light-emitting unit toward the isolation structure, a width of the film thickness reduction region is a first width, the first width being less than or equal to 1.3 times the first height.

A second aspect of the present application discloses a display panel. The display panel includes:
a substrate;
an isolation structure located on a side of the substrate and including a crown and a support portion that are arranged in a stacked manner, the crown being located on a side of the support portion away from the substrate, and an orthographic projection of the support portion on the substrate being within that of the crown on the substrate; and
at least one light-emitting unit located on the same side of the substrate as the isolation structure and including a first functional layer, where
the display panel has cutting planes that pass through a center of the light-emitting unit and are perpendicular to a plane in which the substrate is located, where in any one of the cutting planes, an included angle between a first straight line determined by an edge of a side of the support portion close to the substrate and an edge of the crown and the plane in which the substrate is located is a third included angle, and an included angle between a second straight line determined by an edge of the first functional layer and the edge of the crown and the plane in which the substrate is located is a fourth included angle, the fourth included angle being greater than the third included angle.

A third aspect of the present application provides a preparation method for a display panel. The preparation method includes steps of:
providing a substrate;
preparing a support portion on a side of the substrate;
preparing a crown on a side of the support portion away from the substrate, where an orthographic projection of the support portion on the substrate is within that of the crown on the substrate; and
preparing at least one light-emitting unit on the same side of the substrate, where the light-emitting unit includes a first functional layer, and the first functional layer extends toward the support portion,
where the display panel has cutting planes that pass through a center of the light-emitting unit and are perpendicular to a plane in which the substrate is located, where in any one of the cutting planes, an included angle between a first straight line determined by an edge of a side of the support portion close to the substrate and an edge of the crown and the plane in which the substrate is located is a third included angle, and an included angle between a second straight line determined by an edge of the first functional layer and the edge of the crown and the plane in which the substrate is located is a fourth included angle, the fourth included angle being greater than the third included angle.

A fourth aspect of the present application provides an evaporation device, applied to preparation of the first functional layer in the above-described preparation method for a display panel. The evaporation device includes:
a crucible provided with a cavity for accommodating an evaporation material;
an evaporation source located on a side of the crucible and in communication with the crucible; and
an angle limiting assembly detachably arranged around an outlet of the evaporation source, an end of the angle limiting assembly away from the evaporation source being provided with an evaporation hole for limiting an evaporation range of the evaporation material.

The embodiments of the present application are conducive to avoiding lateral leakage current of the light-emitting unit and improving the low grayscale optical performance of the display panel.

### BRIEF DESCRIPTION OF THE DRAWINGS

FIG. 1 is a schematic view of a display panel in a cutting plane according to a first aspect of the present application;

FIG. 2 is a top view of FIG. 1;

FIG. 3 is a schematic enlarged view of part A in FIG. 1;

FIG. 4 is a schematic partial view of a light-emitting unit of a display panel according to a first aspect of the present application;

FIG. 5 is a schematic partial view of a first functional layer of a display panel according to a first aspect of the present application;

FIG. 6 is a schematic enlarged view of part B in FIG. 5;

FIG. 7 is a schematic sectional view of part of a first functional layer according to a first aspect of the present application;

FIG. 8 is a schematic flow diagram of a preparation method for a display panel according to a second aspect of the present application;

FIG. 9 is a profile view of an evaporation device according to a third aspect of the present application; and

FIG. 10 is a top view of an evaporation device according to a third aspect of the present application.

### DETAILED DESCRIPTION OF THE EMBODIMENTS

Inventors of the present application, during long-term practical work, have found that there is the following problem in the related art: In a display panel, a hole injection layer (HIL), which serves as a main film layer causing crosstalk, tends to overlap with an isolation structure and an auxiliary cathode portion at its edges during evaporation. This results in severe lateral leakage current, which in turn degrades the low grayscale optical performance of the display panel and affects product quality.

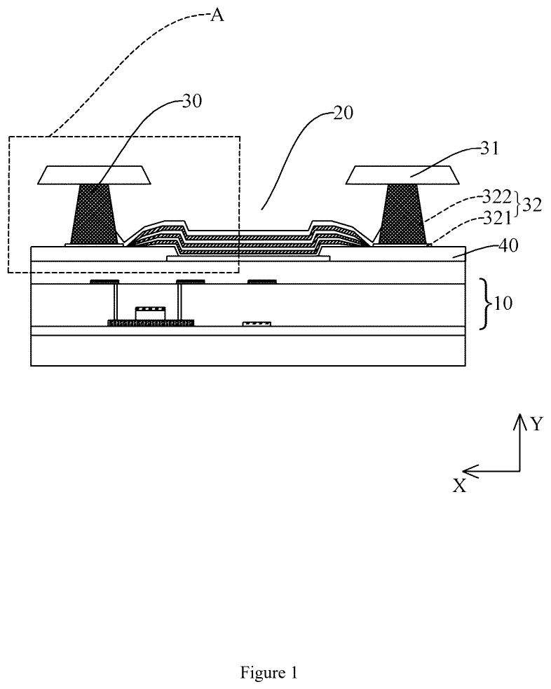

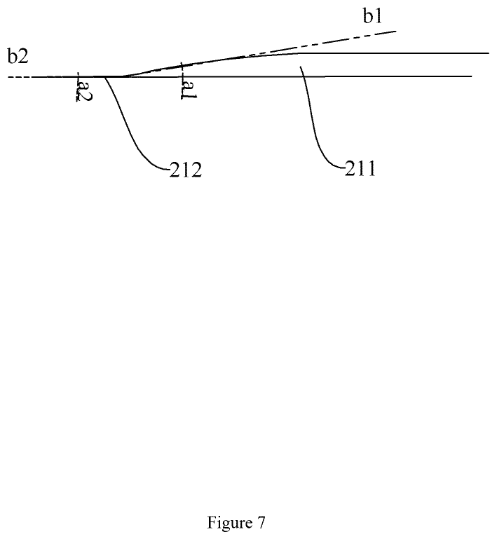

Next, a display panel according to the present application will be described with reference to FIG. 1 to FIG. 7. The display panel includes a substrate 10, an isolation structure 30, and at least one light-emitting unit 20. The isolation structure 30 is located on a side of the substrate 10. The isolation structure 30 encloses at least one isolation opening 310. The isolation structure 30 includes a crown 31 and a support portion 32 that are arranged in a stacked manner. The crown 31 is located on a side of the support portion 32 away from the substrate 10. An orthographic projection of the support portion 32 on the substrate 10 is within that of the crown 31 on the substrate 10. The light-emitting unit 20 is located on the same side of the substrate 10 as the isolation structure 30. The light-emitting unit 20 includes a first functional layer 21, and the first functional layer 21 includes a film thickness reduction region m. In a direction (Z direction) perpendicular to a plane in which the substrate 10 is located, a distance between an end of the support portion 32 away from the substrate 10 and an end of the support portion 32 close to the substrate 10 is a first height h1. In a direction parallel to the plane in which the substrate 10 is located and from the light-emitting unit 20 toward the isolation structure 30, a width of the film thickness reduction region m is a first width L1. The first width L1 is less than or equal to 1.3 times the first height h1 and greater than or equal to 0.7 times the first height h1, that is, 0.7h1≤L1≤1.3h1, and the first functional layer 21 and the support portion 32 of the isolation structure 30 are not in contact with each other and a gap exists therebetween. The isolation structure 30 completely separates the first functional layer 21, to avoid lateral leakage current of the light-emitting unit and improving the low grayscale optical performance of the display panel. The display panel has cutting planes that pass through a center of the light-emitting unit 20 and are perpendicular to the plane in which the substrate 10 is located. In any one of the cutting planes, an included angle between a first straight line p1 determined by an edge of a side of the support portion 32 close to the substrate 10 and an edge of the crown 31 and the plane in which the substrate 10 is located is a third included angle a3, and an included angle between a second straight line p2 determined by an edge of the first functional layer 21 and the edge of the crown 31 and the plane in which the substrate 10 is located is a fourth included angle a4. The third included angle a3 is less than the fourth included angle a4, and in each plane of the isolation opening 310, the first functional layer 21 and the support portion 32 of the isolation structure 30 are not in contact with each other and a gap exists therebetween, to further avoid lateral leakage current of the light-emitting unit and improving the low grayscale optical performance of the display panel.

The composition, preparation, and other contents of the isolation structure (also referred to as a barrier structure or an isolation column) mentioned below are further described in patents Nos. CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A, which are incorporated herein by reference.

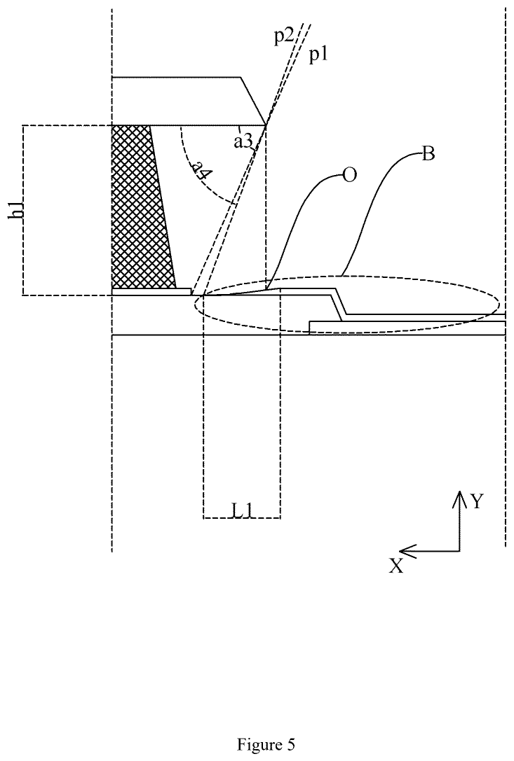

With reference to FIG. 5 to FIG. 7, in one embodiment, since the orthographic projection of the support portion 32 of the isolation structure on the substrate 10 is within that of the crown 31 on the substrate 10, the isolation structure 30 forms a roof structure, which causes an evaporation shadow area during evaporation. For example, during evaporation of the first functional layer 21, the film thickness reduction region m of the first functional layer 21 is formed in the evaporation shadow area. In the present application, the film thickness reduction region m is not only limited to a state where the first functional layer is continuously reduced in thickness in this region, but also includes a state where the first functional layer has a slight increase in thickness during the reduction. In a direction in which the first functional layer 21 extends and is away from the light-emitting unit 20, the film thickness reduction region sequentially includes a first film layer 211 and a second film layer 212 that are continuous. A film thickness of the first film layer 211 and a film thickness of the second film layer 212 gradually decrease in the direction in which the first functional layer 21 extends and is away from the light-emitting unit 20. In the direction (Z direction) perpendicular to the plane in which the substrate 10 is located, a section of the first functional layer 21 includes a tangent b1 to a surface of the first film layer 211 facing away from the substrate 10 and a tangent b2 to a surface of the second film layer facing away from the substrate. The section of the first functional layer 211 passes through the center of the light-emitting unit 20 in which it is located. A first included angle a1 between the tangent b1 to the surface of the first film layer 211 facing away from the substrate 10 and the plane in which the substrate 10 is located is greater than a second included angle a2 between the tangent b2 to the surface of the second film layer 212 facing away from the substrate 10 and the plane in which the substrate 10 is located. Further, the first included angle a1 is between 0° and 90°. Further, the first included angle a1 includes one of 60°, 70°, or 80°. The tangent b2 to the surface of the second film layer 212 facing away from the substrate 10 is parallel or approximately parallel to the plane in which the substrate 10 is located. A film thickness of an end of the second film layer 212 away from the first film layer 211 is equal to 0. A film thickness of an end of the second film layer 212 close to the first film layer 211 is equal to or approximately equal to the film thickness of the end of the second film layer 212 away from the first film layer 211. That is, a film thickness reduction rate of the first film layer 211 is greater than a film thickness reduction rate of the second film layer 212. In the present application, the film thickness of the first functional layer 21 is rapidly reduced at the first film layer 211, which is conducive to the entire thickness of the second film layer 212 approaching 0, and the first functional layer 21 and the isolation structure 30 are not in contact with each other and a gap exists therebetween. The isolation structure 30 completely separates the first functional layer to avoid lateral leakage current of the light-emitting unit 20, thereby achieving an effect of reducing lateral leakage current of the light-emitting unit 20 and improving the low grayscale optical performance of the display panel.

With reference to FIG. 5, in some embodiments, the fourth included angle a4 is between 50° and 70°, and a sum of the third included angle a3 and the fourth included angle a4 is less than 90°. Further, the fourth included angle includes one of 55°, 60°, or 65°. Specifically, the fourth included angle a4 here is an included angle between the second straight line p2 determined by the edge of the second film layer 212 away from the first film layer 211 and the edge of the crown 31 and the plane in which the substrate 10 is located. A length of the first straight line p1 is equal to a shortest distance between the edge of the side of the support portion 32 close to the substrate 10 and the edge of the crown 31. A length of the second straight line p2 is equal to a shortest distance between the edge of the second film layer 212 away from the first film layer 211 and the edge of the crown 31. In one embodiment, the fourth included angle a4 is equivalent to an evaporation angle of the first functional layer 21; that is, the evaporation angle of the first functional layer 21 is greater than the third included angle a3, and the edge of the first functional layer 32 is separated from the support portion 32, thereby achieving the effect of reducing lateral leakage current of the light-emitting unit 20 and improving the low grayscale optical performance of the display panel.

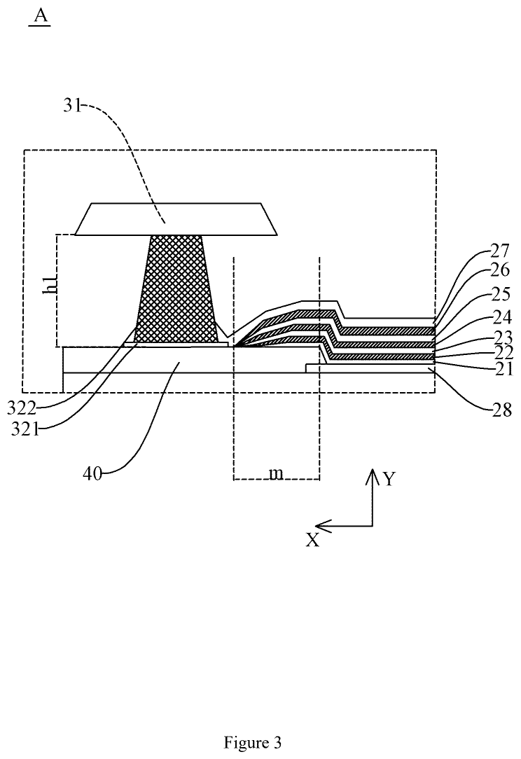

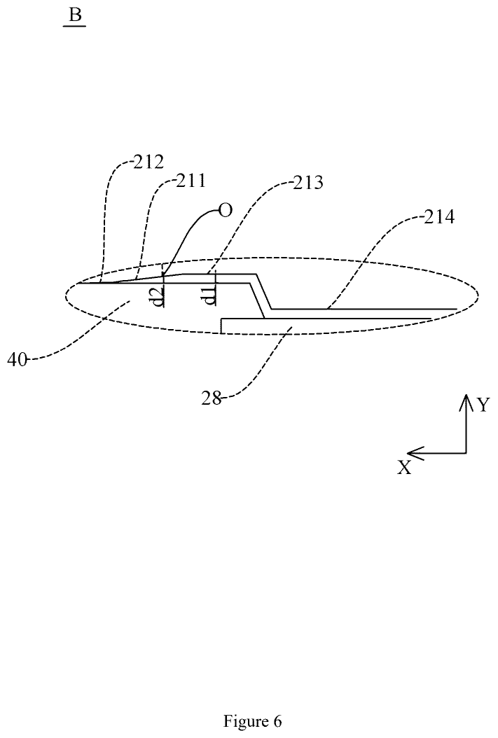

With reference to FIG. 3, FIG. 5, and FIG. 6, in one embodiment, the first functional layer 21 further includes a film thickness flat region 213. The film thickness flat region 213 is located on a side of the first film layer 211 away from the second film layer 212 and is continuous with the first film layer 211. A film thickness of the film thickness flat region 213 is uniform. In the direction (Z direction) perpendicular to the plane in which the substrate 10 is located, the film thickness of the first film layer 211 is less than the film thickness of the film thickness flat region 213.

With reference to FIG. 6, in one embodiment, in the direction (Z direction) perpendicular to the plane in which the substrate 10 is located, the film thickness of the film thickness flat region 213 is a first thickness d1. An orthographic projection point of the edge of the crown 31 on the first film layer 21 is a first projection point O. A film thickness of the first film layer 21 at the first projection point O is a second thickness d2. The second thickness d2 is less than or equal to ⅗ times the first thickness d1 and greater than or equal to ⅖ times the first thickness d1, that is, ⅖d1≤d2≤⅗d1. This design is conducive to controlling the film thickness reduction rate of the first film layer 211 and preventing the second film layer 212 in the first functional layer 21 from extending to the isolation structure 30.

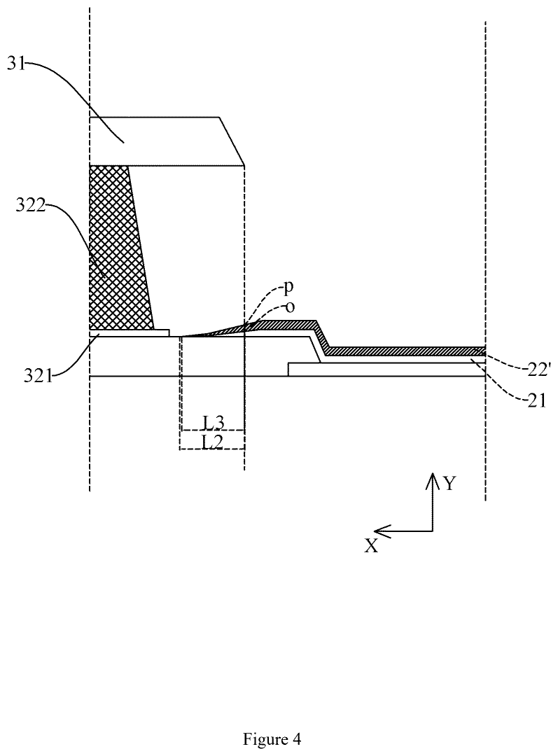

With reference to FIG. 3 and FIG. 4, in one embodiment, the light-emitting unit further includes a second functional layer 22′. The first functional layer 21 includes a first sub-functional layer. At least one second functional layer 22′ is provided on a side of the first sub-functional layer away from the substrate 10. The first sub-functional layer is a hole injection layer (HIL). The first functional layer further includes a second sub-functional layer (not shown in the figures). The second sub-functional layer is located on the side of the first sub-functional layer away from the substrate 10. At least one second functional layer is provided between the second sub-functional layer and the first sub-functional layer, and/or at least one second functional layer is provided on a side of the second sub-functional layer away from the substrate 10. The second sub-functional layer is a charge generation layer, where the charge generation layer (CGL) includes an N-type charge generation layer (N-CGL) and a P-type charge generation layer (P-CGL) that are sequentially stacked. An electrical conductivity of the first functional layer 21 is greater than that of the second functional layer 22′. That is, the first functional layer 21 is a high-conductivity material layer with a higher electrical conductivity. An orthographic projection point of the edge of the crown 31 on each second functional layer 22′ is a second projection point P. In the direction (X direction) parallel to the plane in which the substrate 10 is located, a distance between the second projection point P and an edge of the second functional layer 22′ is a second length L2, and a distance between the first projection point O and an edge of the second film layer 212 is a first length L3. The second length L2 is greater than the first length L3. A reduction rate of the first functional layer 21 in the film thickness reduction region m is greater than that of the second functional layer 22′. Since the first functional layer 21 has a higher electrical conductivity, a short circuit to the isolation structure easily occurs. Therefore, the first functional layer 21 needs to be rapidly reduced in thickness in the film thickness reduction region m, and the film thickness of the first functional layer 32 approaches 0, avoiding an overlap between the first functional layer 21 and the support portion 32 of the isolation structure 30. In addition, a gap is present between the first functional layer 21 and the support portion 32 of the isolation structure 30, and the isolation structure 30 completely separates the first functional layer 21, to avoid lateral leakage current of the light-emitting unit 20.

In one embodiment, the light-emitting unit may be a single-layer OLED device or a stacked OLED device. When the light-emitting unit may be a single-layer OLED device (as shown in FIG. 3), the first functional layer includes a first sub-functional layer. The first sub-functional layer is a hole injection layer (HIL). The light-emitting unit 20 includes a hole transport layer (HTL) 22, an emitting layer (EML) 23, a hole blocking layer (HBL) 24, an electron transport layer (ETL) 25, and an electron injection layer (EIL) 26 that are sequentially stacked on the hole injection layer in a direction away from the substrate 10. A distance between an orthographic projection point of the edge of the crown 31 on the hole injection layer and an edge of the hole injection layer is less than that between an orthographic projection point of the edge of the crown 31 on each second functional layer (such as the hole transport layer 22, the emitting layer 23, the hole blocking layer 24, the electron transport layer 25, and the electron injection layer 26) and an edge of the corresponding second functional layer 22′. When the light-emitting unit is a stacked OLED device, the stacked OLED device means that two or more light-emitting units are vertically stacked to form one OLED device, and the light-emitting units are connected by a charge generation layer (CGL) between them. That is, at least one functional layer includes a first sub-functional layer and a second sub-functional layer. Here, the first sub-functional layer is a hole injection layer, and the second sub-functional layer is a light-emitting material layer, specifically the charge generation layer (CGL), where the charge generation layer (CGL) includes an N-type charge generation layer (N-CGL) and a P-type charge generation layer (P-CGL) that are sequentially stacked. The CGL is configured to generate carriers, transport carriers, and inject carriers, to improve the current efficiency in each emitting layer while ensuring effective distribution of charges to the stacked emitting layers. The second functional layer includes a first hole transport layer, a first emitting layer, and a first electron transport layer that are sequentially stacked on the hole injection layer, and a second hole transport layer, a second emitting layer, a second electron transport layer, and an electron injection layer that are stacked on the charge generation layer. Here, the distance between the orthographic projection point of the edge of the crown 31 on the hole injection layer and the edge of the hole injection layer is equal to that between an orthographic projection point of the edge of the crown 31 on the N-type charge generation layer (N-CGL) and an edge of the N-type charge generation layer (N-CGL), and also equal to that between an orthographic projection point of the edge of the crown 31 on the P-type charge generation layer (P-CGL) and an edge of the P-type charge generation layer (P-CGL). In one embodiment, the P-type charge generation layer (P-CGL), the N-type charge generation layer (N-CGL), and the hole transport layer (HTL) are all high-conductivity material film layers with a high electrical conductivity. Therefore, a distance between a projection point of the crown on the charge generation layer (CGL) and an edge of the charge generation layer (CGL) should also be less than other second lengths. This design prevents the P-type charge generation layer, the N-type charge generation layer (N-CGL), and the hole transport layer (HTL) from being in contact with the support portion or the auxiliary cathode, avoids lateral leakage current of the light-emitting unit, and thus improves the low grayscale optical performance of the display panel.

With reference to FIG. 3, in one embodiment, the light-emitting unit 20 further includes a first electrode 28 and a second electrode 27. The first electrode 28 is located on a side of the first functional layer 21 close to the substrate 10, and the second electrode 27 is located on a side of the first functional layer 21 away from the substrate 10. In one embodiment, one of the first electrode 28 or the second electrode 27 may be used as an anode, and the other may be used as a cathode, to drive the light-emitting unit to emit light. For convenience of description, in an embodiment of the present application, the second electrode 27 is the cathode of the display panel, and the first electrode 28 is the anode of the display panel, for example.

With reference to FIG. 1, FIG. 3, and FIG. 5, in one embodiment, the support portion 32 is a conductive structure, the second electrode 27 is electrically connected to the support portion 32, and the crown 31 may be a conductive structure or a non-conductive structure. For example, the crown 31 may be an inorganic film layer, or the crown may be a conductive material. For example, the conductive material of the crown 31 may be titanium. Further, the support portion 32 includes at least two film layers. For example, the support portion 32 includes a first support layer 321 and a second support layer 322 that are arranged in a stacked manner. The second support layer 322 is located on a side of the first support layer 321 away from the substrate 10. A orthographic projection of the second support layer 322 on the substrate 10 is within that of the first support layer 321 on the substrate 10, and the orthographic projection of the first support layer 321 on the substrate 10 is within that of the crown 21 on the substrate 10, and the second support layer 322 forms a recessed structure relative to the first support layer 321 and the crown 21. The recessed structure prevents excessive waste from entering other positions of the display panel during etching of the second support layer 322. In addition, the first support layer 321 protrudes relative to the second support layer 322, which is conducive to providing an overlapping support effect for the second electrode 27, and the second electrode 27 is better electrically connected to the support portion 32. Further, an edge of the first support layer 321 is an edge of the support portion 32 close to the substrate 10. The first straight line p1 is a straight line determined by the edge of the first support layer 321 and the edge of the crown 31. Further, the first support layer 321 and the second support layer 322 both include conductive materials, and the materials of the first support layer 321 and the second support layer 322 are different. Further, a metal activity of the first support layer 321 is less than that of the second support layer 322. For example, the material of the second support layer 322 may be aluminum, and the material of the first support layer 321 may be molybdenum. Since aluminum has a higher metal activity and molybdenum has a lower metal activity and is more stable, the material of the first support layer 321 is set to be molybdenum to avoid lateral leakage current of the light-emitting unit 20.

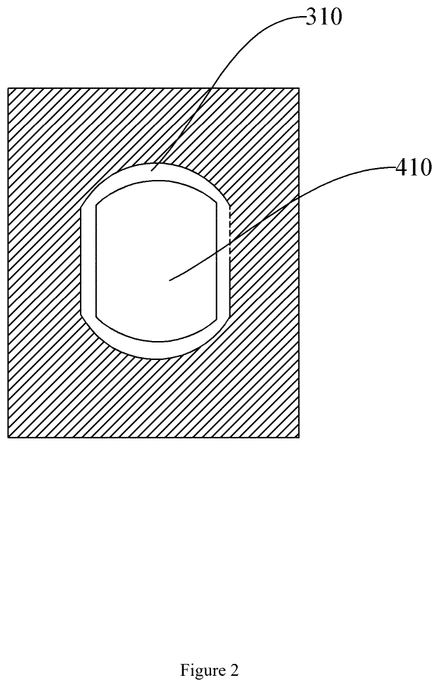

With reference to FIG. 2 and FIG. 3, in one embodiment, the display panel further includes a pixel defining layer 40. The isolation structure 30 is located on a side of the pixel defining layer 40 away from the substrate 10; that is, the pixel defining layer 40 is located between the isolation structure 30 and the substrate 10. The pixel defining layer 40 is provided with at least one pixel opening 410, the light-emitting unit is located in the pixel opening, the pixel opening 410 is in communication with the isolation opening 310, and an orthographic projection of the pixel opening 410 on the substrate 10 is within that of the corresponding isolation opening 310 on the substrate 10. Further, the pixel defining layer 40 is disposed in the same layer as the first electrode 28, and the pixel defining layer 40 covers a gap between adjacent first electrodes 28 and an edge of the first electrode 28, and the pixel opening exposes the first electrode 28. The first functional layer 21 extends to a position between the pixel opening and the support portion and is located on a side of the pixel defining layer away from the substrate. Further, the film thickness reduction region is located at a position between the pixel opening and the support portion, and part of the film thickness flat region is located at a position between the pixel opening and the support portion.

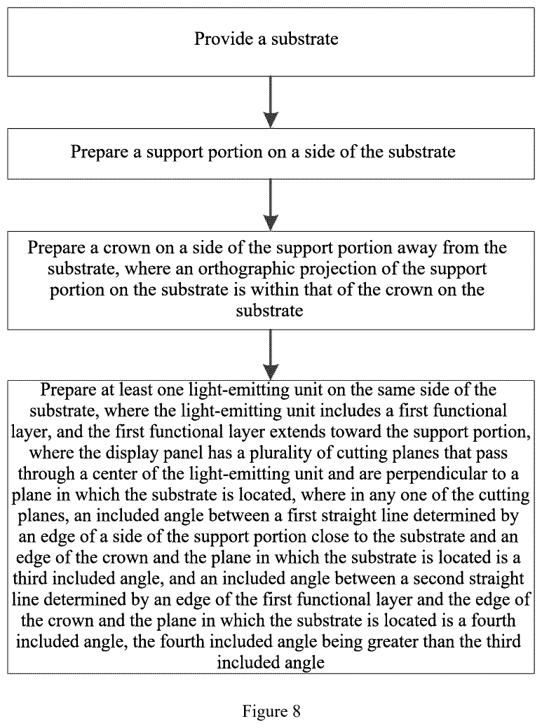

With reference to FIG. 8, based on the embodiments, a second aspect of the present application provides a preparation method for a display panel. The method specifically includes the following steps.
S10: Provide a substrate 10. Specifically, in this step, a first electrode 28 (anode) also needs to be patterned on a side of the substrate 10.
S20: Prepare a support portion 32 on a side of the substrate 10.
S30: Prepare a crown 31 on a side of the support portion 32 away from the substrate 10, where an orthographic projection of the support portion 32 on the substrate 10 is within that of the crown 31 on the substrate 10.
S40: Prepare at least one light-emitting unit 20 on the same side of the substrate 10, where the light-emitting unit 20 includes a first functional layer 21, and the first functional layer 21 extends toward the support portion 32.
   In this step, the first functional layer 21 is formed on the substrate 10 through an evaporation process, and the fourth included angle is between 50° and 70°. Further, the fourth included angle includes one of 55°, 60°, or 65°.

The display panel has cutting planes that pass through a center of the light-emitting unit 20 and are perpendicular to a plane in which the substrate 10 is located, where in any one of the cutting planes, an included angle between a first straight line p1 determined by an edge of a side of the support portion 32 close to the substrate 10 and an edge of the crown 31 and the plane in which the substrate 10 is located is a third included angle a3, and an included angle between a second straight line p2 determined by an edge of the first functional layer 21 and the edge of the crown 31 and the plane in which the substrate 10 is located is a fourth included angle a4, the fourth included angle a4 being greater than the third included angle a3.

Before step S20, the method further includes:
preparing a pixel defining layer 40 on the side of the substrate, including: patterning the pixel defining layer 40 to form at least one pixel opening 410, where the pixel opening 410 exposes at least part of the first electrode 28 (anode).

Step S20 includes: preparing the support portion 32 on a side of the pixel defining layer 40 away from the substrate.

Step S40 includes: preparing the at least one light-emitting unit 20 in the at least one pixel opening 410 on the same side of the substrate 10.

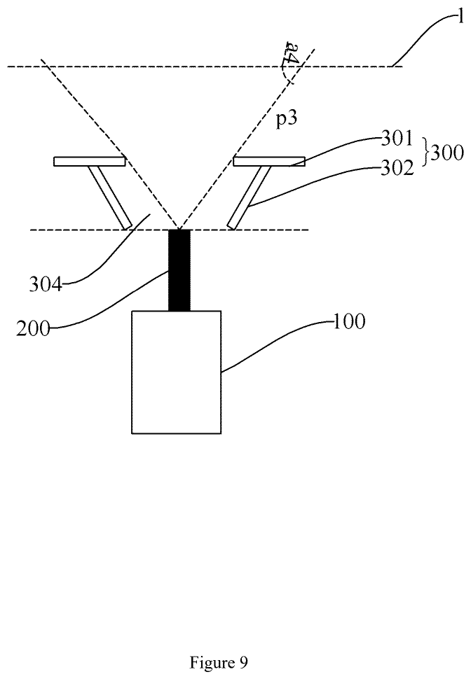

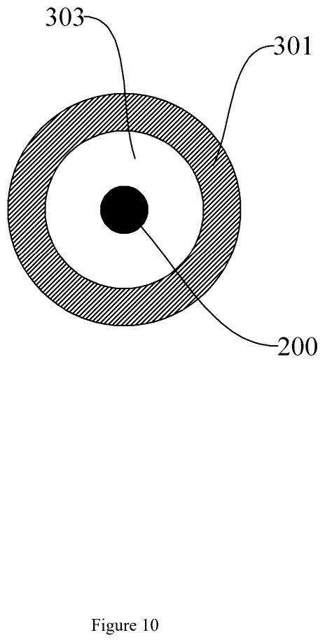

With reference to FIG. 9 and FIG. 10, based on the embodiments, a third aspect of the present application provides an evaporation device. The evaporation device is applied to preparation of the first functional layer 21 in the preparation method for a display panel. The evaporation device includes a crucible 100, an evaporation source 200, and an angle limiting assembly 300. The crucible 100 is provided with a cavity for accommodating an evaporation material. The evaporation source 200 is located on a side of the crucible 100 and in communication with the crucible 100. The angle limiting assembly 300 is detachably arranged around an outlet of the evaporation source 200, an end of the angle limiting assembly away from the evaporation source being provided with an evaporation hole 303 for limiting an evaporation range of the evaporation material. In one embodiment, the evaporation source 200 may be a nozzle.

With continued reference to FIG. 9 and FIG. 10, in one embodiment, the angle limiting assembly 300 includes a first limiting portion 301 and a second limiting portion 302. The second limiting portion 302 is located on a side of the first limiting portion 301 close to the evaporation source 200. The second limiting portion 302 is configured to limit a diffusion range of the evaporation material, that is, to block the evaporation material sprayed from the evaporation source 200 between the first limiting portion 301 and the evaporation source 200, where the evaporation hole 303 is located at a center of the first limiting portion 301, and a shape of the evaporation hole 303 includes circular. Further, an included angle between a connection line between the evaporation source and an edge of the evaporation hole 303 and an evaporation plane 1 is a fourth included angle. The fourth included angle a4 is between 50° and 70°. Further, the fourth included angle includes one of 55°, 60°, or 65°. In one embodiment, the angle limiting assembly is replaceable, and thus different sizes of the evaporation hole 303 may be selected as needed. The second limiting portion 302 has a first through hole 304 in communication with the evaporation hole 303; and an aperture of the first through hole 304 is larger than that of the evaporation hole 303, and the aperture of the first through hole 304 gradually increases in a direction from the evaporation source 200 toward the evaporation hole 303. By providing the second limiting portion 302, the evaporation material sprayed from the evaporation source 200 can be blocked, to avoid lateral leakage of the evaporation material sprayed from the evaporation source 200.

Based on the embodiment, a fourth aspect of the present application provides a display apparatus. The display apparatus includes the display panel provided in the embodiments of the present application. Since the problem solving principle of the display apparatus is similar to that of the display panel, the embodiment of the display apparatus provided in this embodiment of the present application can refer to the embodiment of the display panel provided in the embodiments of the present application, which will not be repeated.

The display apparatus provided in embodiments of the present application may be used in a smart phone, or any electronic product with a display function, including, but not limited to: a television, a notebook computer, a desktop monitor, a tablet computer, a digital camera, a smart bracelet, smart glasses, a vehicle-mounted display, a medical device, an industrial control device, a touch interaction terminal, etc., which is not specifically limited in embodiments of the present application.

1. A display panel, comprising:
a substrate;
an isolation structure, located on a side of the substrate and comprising at least a support portion; and
at least one light-emitting unit, located on the same side of the substrate as the isolation structure and comprising a first functional layer, the first functional layer comprising a film thickness reduction region, wherein
in a direction perpendicular to a plane in which the substrate is located, a distance between an end of the support portion away from the substrate and another end of the support portion close to the substrate is a first height; and in a direction parallel to the plane in which the substrate is located and from the light-emitting unit toward the isolation structure, a width of the film thickness reduction region is a first width, the first width being less than or equal to 1.3 times the first height.

2. The display panel according to claim 1, wherein
the first width is greater than or equal to 0.8 times the first height.

3. The display panel according to claim 1, wherein in a direction in which the first functional layer extends and is away from the light-emitting unit, the film thickness reduction region sequentially comprises a first film layer and a second film layer that are continuous with each other, a minimum film thickness of the first film layer being equal to a maximum film thickness of the second film layer, a film thickness of the first film layer and a film thickness of the second film layer decreasing in the direction in which the first functional layer extends and is away from the light-emitting unit, and a first included angle between a tangent to a surface of the first film layer facing away from the substrate and a plane in which the substrate is located being greater than a second included angle between a tangent to a surface of the second film layer facing away from the substrate and the plane in which the substrate is located;
the first included angle is between 0° and 90°; and
the first width is a distance between an edge of the first film layer away from the second film layer and an edge of the second film layer away from the first film layer.

4. The display panel according to claim 3, wherein
the first functional layer further comprises a film thickness flat region, the film thickness flat region being located on a side of the first film layer away from the second film layer and being continuous with the first film layer, and in the direction perpendicular to the plane in which the substrate is located, the film thickness of the first film layer being less than the film thickness of the film thickness flat region, and
a film thickness at an end of the second film layer away from the first film layer is 0.

5. The display panel according to claim 3, wherein
the isolation structure further comprises a crown located on a side of the support portion away from the substrate, an orthographic projection of the support portion on the substrate being within that of the crown on the substrate; and
in the direction perpendicular to the plane in which the substrate, a film thickness of the film thickness flat region is a first thickness, an orthographic projection point of an edge of the crown on the first film layer is a first projection point, and a thickness of the first film layer at the first projection point is a second thickness, the second thickness being less than or equal to ⅗ times the first thickness and greater than or equal to ⅖ times the first thickness.

6. The display panel according to claim 5, wherein
the light-emitting unit further comprises a second functional layer, the first functional layer comprises a first sub-functional layer, and at least one second functional layer is provided on a side of the first sub-functional layer away from the substrate, the first sub-functional layer comprises a hole transport layer; and
the first functional layer further comprises a second sub-functional layer located on a side of the first sub-functional layer away from the substrate, and the at least one second functional layer is provided between the second sub-functional layer and the first sub-functional layer.

7. The display panel according to claim 6, wherein
the at least one second functional layer is provided on a side of the second sub-functional layer away from the substrate;
the second sub-functional layer comprises a light-emitting material layer; an electrical conductivity of the first functional layer is greater than that of the second functional layer; and
an orthographic projection point of the edge of the crown on the second functional layer is a second projection point, and in a direction parallel to the plane in which the substrate is located, a distance between the second projection point and an edge of the second functional layer is a second length, and a distance between the first projection point and an edge of the first functional layer is a first length, the second length being greater than the first length.

8. The display panel according to claim 4, further comprising a pixel defining layer, the isolation structure being located on a side of the pixel defining layer away from the substrate, the pixel defining layer being provided with at least one pixel opening, and the light-emitting unit being located within the pixel opening;
wherein the isolation structure encloses at least one isolation opening, an orthographic projection of the pixel opening on the substrate being within that of the isolation opening on the substrate;
the first functional layer extends to a position between the pixel opening and the support portion and is located on a side of the pixel defining layer away from the substrate;
the film thickness reduction region is located at a position between the pixel opening and the support portion; and
part of the film thickness flat region is located at a position between the pixel opening and the support portion.

9. The display panel according to claim 5, wherein
the display panel has a plurality of cutting planes that pass through a center of the light-emitting unit and are perpendicular to the plane in which the substrate is located, wherein in any one of the cutting planes, an included angle, between a first straight line determined by an edge of a side of the support portion close to the substrate and the edge of the crown and the plane in which the substrate is located, is a third included angle, and an included angle between a second straight line determined by an edge of the first functional layer and the edge of the crown and the plane in which the substrate is located is a fourth included angle, the fourth included angle being greater than the third included angle;
the fourth included angle is between 50° and 70°, a sum of the third included angle and the fourth included angle being less than 90°;
the fourth included angle is an included angle between the second straight line determined by the edge of the second film layer away from the first film layer and the edge of the crown and the plane in which the substrate is located; and
a length of the first straight line is equal to a shortest distance between the edge of the side of the support portion close to the substrate and the edge of the crown, and a length of the second straight line is equal to a shortest distance between the edge of the second film layer away from the first film layer and the edge of the crown.

10. The display panel according to claim 9, wherein
the support portion comprises a first support layer and a second support layer that are arranged in a stacked manner, the second support layer being located on a side of the first support layer away from the substrate, an orthographic projection of the second support layer on the substrate being within that of the first support layer on the substrate, and the first support layer and the second support layer both comprising conductive materials; an edge of the first support layer is an edge of the support portion close to the substrate; the first straight line is a straight line determined by the edge of the first support layer and the edge of the crown.

11. A display panel, comprising:
a substrate;
an isolation structure, located on a side of the substrate, and comprising a crown and a support portion that are arranged in a stacked manner, the crown being located on a side of the support portion away from the substrate, and an orthographic projection of the support portion on the substrate being within that of the crown on the substrate; and at least one light-emitting unit, located on the same side of the substrate as the isolation structure, and comprising a first functional layer, wherein
the display panel has a plurality of cutting planes that pass through a center of the light-emitting unit and are perpendicular to a plane in which the substrate is located, wherein in any one of the cutting planes, an included angle between a first straight line determined by an edge of a side of the support portion close to the substrate and an edge of the crown and the plane in which the substrate is located is a third included angle, and an included angle between a second straight line determined by an edge of the first functional layer and the edge of the crown and the plane in which the substrate is located is a fourth included angle, the fourth included angle being greater than the third included angle.

12. The display panel according to claim 11, wherein
the fourth included angle is between 50° and 70°, a sum of the fourth included angle and the third included angle being less than 90°; and
a length of the first straight line is equal to a shortest distance between the edge of the side of the support portion close to the substrate and the edge of the crown, and a length of the second straight line is equal to a shortest distance between the edge of the first functional layer and the edge of the crown.

13. The display panel according to claim 11, wherein
further comprising a pixel defining layer, the isolation structure being located on a side of the pixel defining layer away from the substrate, the pixel defining layer being provided with at least one pixel opening, and the light-emitting unit being located within the pixel opening.

14. The display panel according to claim 13, wherein
the isolation structure encloses at least one isolation opening, an orthographic projection of the pixel opening on the substrate being within that of the isolation opening on the substrate; and
the first functional layer extends to a position between the pixel opening and the support portion and is located on a side of the pixel defining layer away from the substrate.

15. The display panel according to claim 11, wherein
the support portion comprises a first support layer and a second support layer that are arranged in a stacked manner, the second support layer being located on a side of the first support layer away from the substrate, an orthographic projection of the second support layer on the substrate being within that of the first support layer on the substrate, and the first support film layer and the second support film layer both comprising conductive materials;
an edge of the support portion close to the substrate is an edge of the first support layer;
the first straight line is determined by the edge of the first support layer and the edge of the crown; and
the first support film layer comprises molybdenum, and the second support film layer comprises aluminum.

16. A preparation method for a display panel, comprising steps of:
providing a substrate;
preparing a support portion on a side of the substrate;
preparing a crown on a side of the support portion away from the substrate, wherein an orthographic projection of the support portion on the substrate is within that of the crown on the substrate; and
preparing at least one light-emitting unit on the same side of the substrate, wherein the light-emitting unit comprises a first functional layer, and the first functional layer extends toward the support portion,
wherein the display panel has a plurality of cutting planes that pass through a center of the light-emitting unit and are perpendicular to a plane in which the substrate is located, wherein in any one of the cutting planes, an included angle between a first straight line determined by an edge of a side of the support portion close to the substrate and an edge of the crown and the plane in which the substrate is located is a third included angle, and an included angle between a second straight line determined by an edge of the first functional layer and the edge of the crown and the plane in which the substrate is located is a fourth included angle, the fourth included angle being greater than the third included angle.

17. The preparation method for a display panel according to claim 16, wherein a first functional layer is formed on the substrate through an evaporation process, and the fourth included angle is between 50° and 70°.

18. The preparation method for a display panel according to claim 16, wherein before preparing the support portion on the side of the substrate, the method further comprises:
preparing a pixel defining layer on the side of the substrate; and
patterning the pixel defining layer to form at least one pixel opening; wherein the preparing the support portion on the side of the substrate comprises:
preparing the support portion on a side of the pixel defining layer away from the substrate; and
wherein the preparing the at least one light-emitting unit on the same side of the substrate comprises:
preparing the at least one light-emitting unit in the at least one pixel opening on the same side of the substrate.

19. An evaporation device, applied to preparation of the first functional layer in the preparation method for a display panel according to claim 16, the evaporation device comprising:
a crucible provided with a cavity for accommodating an evaporation material; an evaporation source located on a side of the crucible and in communication with the crucible; and
an angle limiting assembly, detachably arranged around an outlet of the evaporation source, an end of the angle limiting assembly away from the evaporation source being provided with an evaporation hole for limiting an evaporation range of the evaporation material.

20. The evaporation device according to claim 19, wherein
the angle limiting assembly comprises:
a first limiting portion, wherein the evaporation hole is located at a center of the first limiting portion;
a second limiting portion, located on a side of the first limiting portion close to the evaporation source and having a first through hole in communication with the evaporation hole, wherein an aperture of the first through hole is larger than that of the evaporation hole, and the second limiting portion is configured to limit a diffusion range of the evaporation material;
a shape of the evaporation hole comprises circular;
an orthographic projection of the first through hole on the first limiting portion covers the evaporation hole;
in a direction from the evaporation source toward the evaporation hole, the aperture of the first through hole gradually increases; and
an included angle between a connection line between the evaporation source and an edge of the evaporation hole and an evaporation plane is a fourth included angle, the fourth included angle being between 50° and 70°.
